(19) United States
(12) Patent Application Publication
(10) Pub. No.: US 2012/0012382 A1
(43) Pub. Date: Jan. 19, 2012

(54) Conductive Films for EMI Shielding Applications

(75) Inventors: Douglas McBain, Wadsworth, OH (US); Richard F. Hill, Parkman, OH (US)

(73) Assignee: LAIRD TECHNOLOGIES, INC., Chesterfield, MO (US)

(21) Appl. No.: 13/243,685

(22) Filed: Sep. 23, 2011

Related U.S. Application Data
(63) Continuation of application No. PCT/US2009/043716, filed on May 13, 2009.

(51) Int. Cl. H05K 9/00; B32B 37/02; B32B 37/14; H05K 13/00

(52) U.S. Cl. 174/388; 156/212; 156/60; 977/755

(57) ABSTRACT

According to various aspects, exemplary embodiments are provided of EMI shielding materials. In one exemplary embodiment, an EMI shielding material generally includes a conductive metal layer disposed on a thin carrier film. The EMI shielding material may be sufficiently compliant such that the conductive metal layer and thin carrier film are capable of conforming to an irregular surface when the EMI shielding material is applied to the irregular surface.

### CROSS REFERENCE TO RELATED APPLICATION

This patent application is a continuation of and claims the benefit of International Application No. PCT/US2009/043716 filed May 13, 2009. The disclosure of the application identified in this paragraph is incorporated herein by reference in its entirety.

### FIELD

The present disclosure generally relates to Electromagnetic Interference (EMI), and more particularly (but not exclusively) to conductive films for EMI shielding applications.

### BACKGROUND

This section provides background information related to the present disclosure which is not necessarily prior art.

Electronic equipment, devices, components, parts, etc. generate undesirable electromagnetic energy that can interfere with the operation of proximately located electronic equipment. Such EMI interference may adversely affect the operating characteristics of the electrical component and the operation of the associated device.

Accordingly, it is not uncommon to provide shielding and/or grounding for electronic components that use circuitry that emits or is susceptible to electromagnetic interference. These components may be shielded to reduce undesirable electromagnetic interference and/or susceptibility effects with the use of a conductive shield that reflects or dissipates electromagnetic charges and fields. Such shielding may be grounded to allow the offending electrical charges and fields to be dissipated without disrupting the operation of the electronic components enclosed within the shield. By way of example, sources of undesirable electromagnetic energy are often shielded by a stamped metal enclosure.

In addition, electrical components, such as semiconductors, transistors, etc., typically have pre-designed temperatures at which the electrical components optimally operate. Ideally, the pre-designed temperatures approximate the temperature of the surrounding air. But the operation of electrical components generates heat which, if not removed, will cause the electrical component to operate at temperatures significantly higher than its normal or desirable operating temperature. Such excessive temperatures may adversely affect the operating characteristics of the electrical component and the operation of the associated device.

To avoid or at least reduce the adverse operating characteristics from the heat generation, the heat should be removed, for example, by conducting the heat from the operating electrical component to a heat sink. The heat sink may then be cooled by conventional convection and/or radiation techniques. During conduction, the heat may pass from the operating electrical component to the heat sink either by direct surface contact between the electrical component and heat sink and/or by contact of the electrical component and heat sink surfaces through an intermediate medium or thermal interface material (TIM). The thermal interface material may be used to fill the gap between thermal transfer surfaces, in order to increase thermal transfer efficiency as compared to having the gap filled with air, which is a relatively poor thermal conductor. In some devices, an electrical insulator may also be placed between the electrical component and the heat sink, in many cases this is the TIM itself.

As used herein, the term electromagnetic interference (EMI) should be considered to generally include and refer to both electromagnetic interference (EMI) and radio frequency interference (RFI) emissions. The term “electromagnetic” should be considered to generally include and refer to both electromagnetic and radio frequency from external sources and internal sources. Accordingly, the term shielding (as used herein) generally includes and refers to both EMI shielding and RFI shielding, for example, to prevent (or at least reduce) ingress and egress of EMI and RFI relative to a shielding device in which electronic equipment is disposed.

### SUMMARY

This section provides a general summary of the disclosure, and is not a comprehensive disclosure of its full scope or all of its features.

According to various aspects, exemplary embodiments are provided of EMI shielding materials. In one exemplary embodiment, an EMI shielding material generally includes a conductive metal layer disposed on a thin carrier film. The EMI shielding material may be sufficiently compliant such that the conductive metal layer and thin carrier film are capable of conforming to an irregular surface when the EMI shielding material is applied to the irregular surface.

In another exemplary embodiment, an EMI shielding material generally includes a conductive metal layer disposed on the thin carrier film. The conductive metal layer is sufficiently thin such that the EMI shielding material is capable of conforming to an irregular surface when the EMI shielding material is applied to the irregular surface.

In a further exemplary embodiment, an EMI shielding material generally includes a thin carrier film having a first side and conductive metal layer applied to the first side of the thin carrier film. The conductive metal layer and the thin carrier film together may have a combined thickness that is sufficiently thin to enable the EMI shielding material to conform to an irregular surface when the EMI shielding material is applied to the irregular surface.

Additional aspects provide methods relating to EMI shielding materials, such as methods of using and/or making the EMI shielding materials. In one exemplary embodiment, a method for making an EMI shielding material generally includes depositing conductive metal onto a carrier film, to thereby form a conductive metal layer. A method may also include applying the EMI shielding material to a plastic article, whereby the EMI shielding material is operable for imparting EMI shielding capability to the plastic article. Additionally, or alternatively, a method may include applying a release liner to the conductive metal layer.

Further aspects and features of the present disclosure will become apparent from the detailed description provided hereinafter. In addition, any one or more aspects of the present disclosure may be implemented individually or in any combination with any one or more of the other aspects of the present disclosure. It should be understood that the detailed description and specific examples, while indicating exemplary embodiments of the present disclosure, are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a cross-sectional view of an EMI shielding material having a conductive metal layer on a transfer film, according to exemplary embodiments;

FIG. 2 is a cross-sectional view of another exemplary embodiment of a an EMI shielding material having a conductive metal layer on a transfer film, according to exemplary embodiments;

FIG. 3 is a process flow diagram of an exemplary method for preparing an EMI shielding material for application to an article or component;

FIG. 4 is a process flow diagram of another exemplary method for preparing an EMI shielding material for application to an article or component;

FIG. 5 is a cross-sectional view of another exemplary embodiment of a an EMI shielding material having a conductive metal layer on a transfer film, according to exemplary embodiments; and

FIGS. 6 and 7 illustrate exemplary patterns in which a release film may be further provided, according to exemplary embodiments.

Corresponding reference numerals indicate corresponding parts throughout the several views of the drawings.

### DETAILED DESCRIPTION

Example embodiments will now be described more fully with reference to the accompanying drawings.

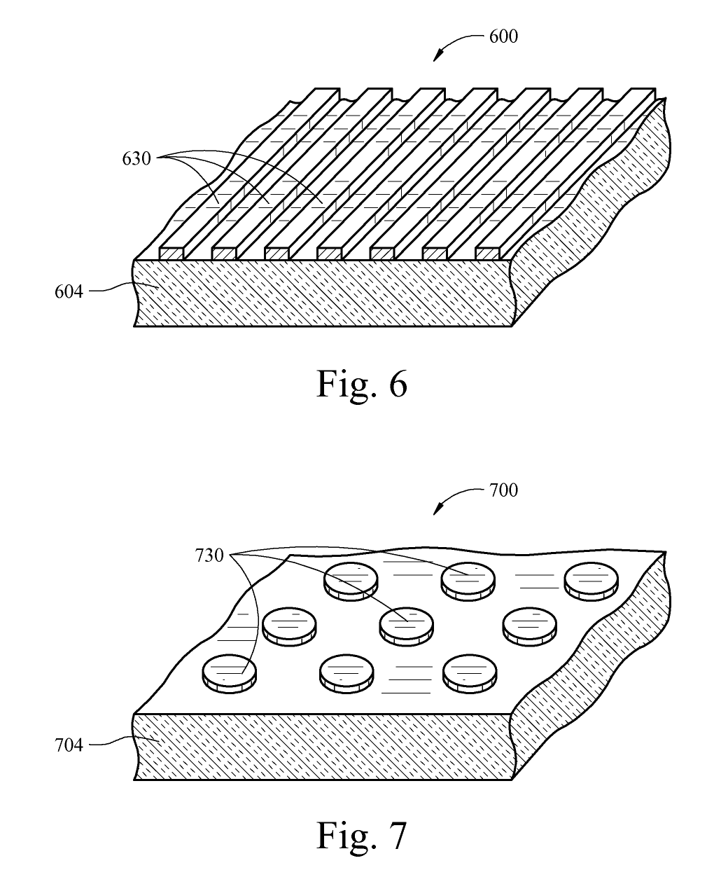

Disclosed herein are various exemplary embodiments of Electromagnetic Interference (EMI) shielding materials that include a conductive metal layer and a thin carrier film material (e.g., a thin layer of polymer or release material, etc.). Some exemplary embodiments may optionally include a release coating and/or film disposed across an entire surface of the conductive metal layer. Yet other exemplary embodiments may optionally include a release coating and/or film disposed across only portions of that entire surface, such as in a predetermined pattern (e.g., striped pattern (FIG. 6) and/or dotted pattern (FIG. 7), etc.).

In various embodiments, an EMI shielding material includes a thin carrier film and a conductive metal layer disposed on the thin carrier film, which is sufficiently compliant such that the conductive metal layer and thin carrier film are able to conform to an irregular surface (e.g., a non-uniform surface that is not flat or continuous, a non-flat surface, curved surface, uneven surface, surface without symmetry, even shape, or formal arrangement, etc.), such as one or more surfaces within a mold cavity or one or more surfaces of a molded article on which the EMI shielding material is intended to be or is applied. Advantageously, this allows the EMI shielding material to become part of a molded article, with the conductive metal layer disposed on the exterior of the molded article and the thin carrier film adhered to the molded article.

In one or more exemplary embodiments, the conductive metal layer has a thickness of less than or equal to 0.0005 inches, and the thin carrier film has a thickness of less than or equal to about 0.001 inches. In other exemplary embodiments, the conductive metal layer may have a thickness falling within a range of about 5 Nanometers (50 Angstroms) to about 100 Nanometers (1000 Angstroms), and the thin carrier film may have a thickness falling within a range of about 0.2 micrometers to about 5 micrometers. In such embodiments, the conductive metal layer may have a thickness of 5 Nanometers, 100 Nanometers, or any value falling between 5 Nanometers and 100 Nanometers, and the thin carrier film may have a thickness of 0.2 micrometers, 5 micrometers, or any value falling between 0.2 micrometers and 5 micrometers. These numerical dimensions disclosed herein are provided for illustrative purposes only. The particular dimensions are not intended to limit the scope of the present disclosure, as the dimensions may be varied for other embodiments depending, for example, on the particular application in which the embodiment will be used.

The conductive metal layer and the thin carrier film together may have a combined thickness that is effective to enable the EMI shielding material to conform to an irregular surface when the EMI shielding material is applied to the irregular surface. The application of the metallized transfer film or conductive metal layer to a irregular surface of a molded article may provide or imparts EMI shielding capability to the molded part, without requiring the article to be molded or made of a conductive plastic or painted with a conductive paint.

In addition, the metallized transfer film or conductive metal layer on a carrier film, and release coating and/or film may also provide for or establish a heat-conducting path. The thinness of the metallized transfer film and release coating and/or film also allows for good conformance with the mating surface, and helps improve thermal conduction. Thermal conduction depends, at least in part, upon the degree of effective surface area contact with the conductive metal layer. The ability to conform to a mating surface is important, as a molded article for EMI shielding may not be perfectly flat or smooth, and any air gaps or spaces between the conductive metal layer and article surfaces would decrease thermal conductivity (air being a relatively poor thermal conductor). Therefore, removal of air spaces may help increase thermal conductivity to the conductive metal layer.

Some alternative exemplary embodiments disclosed herein may also include a protective liner disposed on a side of the EMI shielding material opposite the thin carrier film. The protective liner may preferably disposed over the metallized transfer layer or conductive metal layer, and may be removed before application or deposition of the EMI shielding material onto a surface. Use of the protective liner may help reduce the chance of surface imperfections as a result of handling the EMI shielding material. The protective liner may be configured to help protect the conductive metal layer and/or release coating during transport, shipping, handling, etc. In addition, some alternative exemplary embodiments may also include a release coating, which is a low surface energy coating that allows for easy removal of the EMI shielding material from a surface in contact with the release coating. Some embodiments may include a release coating having a thickness of 0.0005 inches or less, e.g., 0.0005 inches, 5 angstroms, etc. In embodiments having a release coating or liner, the protective liner may be disposed over the release coating or liner on the side of the EMI shielding material that is opposite the thin carrier film. Some embodiments may include a release liner having thickness falling within a range of about 1 mil (0.025 millimeters) to about 10 mils (0.25 millimeters). In such embodiments, the release liner may have a thickness of 1 mil, 10 mils, or any value falling between 1 mil and 10 mils. These numerical dimensions disclosed herein are provided for illustrative purposes only. The particular dimensions are not intended to limit the scope of the present disclosure, as the dimensions may be varied for other embodiments depending, for example, on the particular application in which the embodiment will be used.

In addition, the thin carrier film material may provide improved consistency in product thickness and strength with less adverse impact on the electrical conductivity of the metal layer, as compared to plated metal layers whose electrical conductivity is dependent on consistent deposition onto the article. In various embodiments, the thin carrier film material preferably comprises at least one or more of polymer, teflon, polyester, acrylic, or plastic. In some embodiments, the thin carrier film material preferably has a thickness of less than or equal to about 100 gauge or 25 microns/micrometers (0.001 inches), which is sufficiently thin to effectively enable the EMI shielding material to conform to an irregular surface on which the EMI shielding material is intended to be applied. By way of further example, the thin carrier film may have a thickness falling within a range of about 0.2 micrometers to about 5 micrometers, such that the thin carrier film may have a thickness of 0.2 micrometers, 5 micrometers, or any value falling between 0.2 micrometers and 5 micrometers. These numerical dimensions disclosed herein are provided for illustrative purposes only. The particular dimensions are not intended to limit the scope of the present disclosure, as the dimensions may be varied for other embodiments depending, for example, on the particular application in which the embodiment will be used.

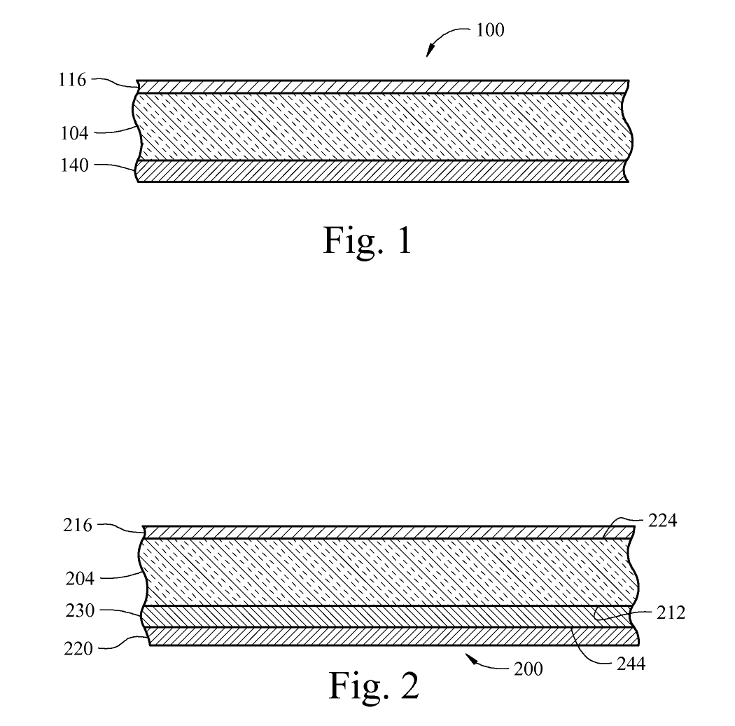

Referring now to FIG. 1, there is shown an exemplary embodiment of an EMI shielding material 100 embodying one or more aspects of the present disclosure. The EMI shielding material 100 generally includes a metallized transfer layer or conductive metal layer 104, a thin carrier film 116, and a protective polymer liner 140 directly on top of the conductive metal layer 104. Accordingly, this particular embodiment of the EMI shielding material 100 initially includes three layers that form a material stack or multi-layered construction. In this particular example, the EMI shielding material 100 may be positioned within a mold cavity (after removal of the protective liner 140), with the conductive metal layer 104 against the surface of the cavity walls to allow the EMI shielding material 100 to become part of a molded article, whereby the conductive metal layer 104 would be disposed on and outwardly facing relative to the exterior of the molded article.

Thin carrier film 116 may preferably comprise at least one or more of polymer, teflon, polyester, acrylic, or plastic. In addition, the thin carrier film 116 may be configured to have a thickness of less than or equal to about 100 gauge or 25 microns/micrometers (0.001 inches), which is sufficiently thin to effectively enable the EMI shielding material 100 to conform to an irregular surface (e.g., surface inside a mold cavity, etc.) on which the EMI shielding material 100 is intended to be applied. Alternatively, the thin carrier film may be made from other materials and/or be thicker or thinner than 25 micrometers or 0.001 inches. For example, the thin carrier film may have a thickness falling within a range of about 0.2 micrometers to about 5 micrometers, such that the thin carrier film may have a thickness of 0.2 micrometers, 5 micrometers, or any value falling between 0.2 micrometers and 5 micrometers. These numerical dimensions disclosed herein are provided for illustrative purposes only, as the dimensions may be varied for other embodiments depending, for example, on the particular application in which the embodiment will be used.

The metallized transfer layer or conductive metal layer 104 may be directly provided or applied to a side of the thin carrier film 116. For example, the metallized transfer layer or conductive metal layer 104 may be applied or provided via vapor deposition, vacuum metallization, sputtering, flash coating, electrolytic plating, evaporating, coating using gravure, flexographic coating, printing material in a pattern, other coating technologies, among other suitable processes.

The metalized transfer layer or conductive metal layer 104 may disposed on the thin carrier film 116, such that the conductive metal layer 104 has a sufficient thinness of less than or equal to 0.0005 inches, to allow the EMI shielding material 100 to conform to an irregular surface on which the EMI shielding material 100 is intended to be applied. In one or more exemplary embodiments, the conductive metal layer 104 may have a thickness falling within a range of about 5 Nanometers (50 Angstroms) to about 100 Nanometers (1000 Angstroms), such that the conductive metal layer 104 has a thickness of 5 Nanometers, 100 Nanometers, or any value falling between 5 Nanometers and 100 Nanometers. These numerical dimensions disclosed herein are provided for illustrative purposes only, as the dimensions may be varied for other embodiments depending, for example, on the particular application in which the embodiment will be used.

The metallized transfer layer or conductive metal layer 104 may be formed from various materials, which preferably are good electrical and thermal conductors and are relatively compliant, conformable, or flexible for conforming to a surface (e.g., a surface within a mold cavity, a surface of a molded article, a surface of an electrical component or heat sink, etc.). Using a material that is a good thermal conductor and capable of good conformance with a mating surface helps provide improved thermal conductivity. In addition, the metallized transfer layer or conductive metal layer 104 may also be configured to help the EMI shielding material 100 release cleanly and easily from an electrical component or heat sink, for example, for reworking or servicing the electrical component. In some exemplary embodiments, the metallized transfer layer or conductive metal layer 104 comprises copper or copper alloy. Alternative embodiments may include one or more other materials and/or different thicknesses used for the metallized transfer layer or conductive metal layer 104, including other metals besides copper (e.g., aluminum, silver, tin, etc.). By way of further example, exemplary embodiments may include a metallized transfer layer or conductive metal layer 104 comprising aluminum having a thickness of less than or equal to about 0.0005 inches. Other embodiments may have a metallized transfer layer or conductive metal layer 104 with a thickness of about 0.0002 inches, 0.0001 inches, 5 angstroms, less than 0.0001 inches, less than 5 angstroms, 5 Nanometers (50 Angstroms), 100 Nanometers (1000 Angstroms), a value falling between 5 Nanometers and 100 Nanometers, etc. These numerical dimensions disclosed herein are provided for illustrative purposes only, as the dimensions may be varied for other embodiments depending, for example, on the particular application in which the embodiment will be used.

Also disclosed herein, the metallized transfer film or conductive metal layer 104 may be provided in some embodiments as a subcomponent or part of a product from the Dunmore Corporation of Bristol, Pa., such as products under the trade name Dun-Tran (e.g., Dunmore DT273 metallized film having a heat-activated adhesive layer, Dunmore DT101 metallization transfer layer, etc.) or other products having a metallization or metal layer or film with a polymer coating.

The table immediately below lists various exemplary materials that may be used as a metallized transfer layer or conductive metal layer 104 in any one or more exemplary embodiments described and/or shown herein. This table and the materials and properties listed therein are provided for purposes of illustration only and not for purposes of limitation.

| | Construction | |
|---|---|---|
| Name | Composition | Film |
| Dun-Tran-DT101 | Aluminum | Polyester |
| Dun-Tran-DT273 | Aluminum | Siliconized |
| | | polyester |
| DunILam-DM101 | Aluminum | Acrylic |
| DunI-Met-DE502 | Silver | Teflon |

Various processes and technologies may be employed to provide a metallized transfer layer or conductive metal layer 104 on a carrier film, depending on the particular embodiment. Some example processes include vapor deposition, vacuum metallization, lamination, calendaring, sputtering, electrolytic plating, evaporating, flash coating, coating using gravure, flexographic coating, printing in a pattern, other coating technologies, transferring or providing via a transfer carrier (e.g., polyester liner, etc.), among other suitable processes. By way of example, a metallized transfer layer or conductive metal layer 104 may be configured to release from a carrier film for transfer to a molded article or electrical component, for example.

In addition, FIG. 1 only shows a single metallized transfer layer or conductive metal layer 104. Alternative embodiments may include more than one conductive metal layer 104 (e.g., multiple layers of different metal materials, multiple layers of the same material, multiple layers of different alloys, etc.) disposed, coated, transferred, applied, or otherwise provided fully or partially on a carrier film. For example, another embodiment may include a first copper metal layer formed directly on top of the carrier film 116, and a second nickel metal layer formed directly on top of the copper layer, for example, through sputtering technology to improve oxidation resistance.

Another example may include a conductive metal layer formed directly on top of the carrier film 116 with a protective polymer liner 140 directly on top of the conductive metal layer 104, as shown in FIG. 1. In embodiments that include the protective liner 140 like that shown in FIG. 1, the protective liner 140 may be removed before the EMI shielding material 100 is inserted within a mold cavity for injection molding, or prior to application of the EMI shielding material 100 to a surface of an article or component. As disclosed herein, a metallized transfer layer or conductive metal layer 104 may be provided by way of depositing one or more metals (e.g., copper, aluminum, etc.) onto a carrier film (e.g., polymer, plastic, paper, dry film materials, transfer film materials, etc.). Some example processes by which metal material may be provided include vapor deposition, vacuum metallization, lamination, calendaring, sputtering, electrolytic plating, evaporating, flash coating, coating using gravure, flexographic coating, printing dry material in a pattern, other coating technologies, transferring or providing via a transfer carrier (e.g., polyester liner, etc.), among other suitable processes.

Referring now to FIG. 2, there is shown an alternate exemplary embodiment of an EMI shielding material 200 embodying one or more aspects of the present disclosure. As shown in FIG. 2, the EMI shielding material 200 generally includes a metallized transfer layer or conductive metal layer 204 and a thin carrier film 216. In this particular embodiment, the EMI shielding material 200 further includes a release liner 230 and release coating 220. Accordingly, this particular embodiment of the EMI shielding material 200 initially includes four layers that form a material stack or multi-layered construction. In this alternate exemplary embodiment, the EMI shielding material 200 may be directly applied to the surface of a molded article or electrical component, with the release coating against the surface of a molded article or component, such that the EMI shielding material may subsequently be removed to permit rework or replacement of components.

As shown in FIG. 2, the illustrated EMI shielding material 200 generally includes a metallized transfer layer or conductive metal layer 204 on a thin carrier film material (e.g., dry film or layer, etc.) 216, a release liner 230, and a release coating 220 (or more broadly, substrates or supporting layers 220 and 230). The metallized transfer layer or conductive metal layer 204 may be directly provided or applied to a side of the thin carrier film 216. The various portions 204, 216, 220 and 230 of the EMI shielding material 200 are described in more detail herein.

The thin carrier film 216 may preferably have a thickness of less than or equal to about 100 gauge or 25 microns/micrometers (0.001 inches), which is sufficiently thin to effectively enable the EMI shielding material 200 to conform to an irregular surface on which the EMI shielding material 200 is intended to be applied. Alternatively, the thin carrier film may be made from other materials and/or be thicker or thinner than 25 micrometers or 0.001 inches. For example, the thin carrier film may have a thickness falling within a range of about 0.2 micrometers to about 5 micrometers, such that the thin carrier film may have a thickness of 0.2 micrometers, 5 micrometers, or any value falling between 0.2 micrometers and 5 micrometers. These numerical dimensions disclosed herein are provided for illustrative purposes only, as the dimensions may be varied for other embodiments depending, for example, on the particular application in which the embodiment will be used.

With continued reference to FIG. 2, the metalized transfer layer or conductive metal layer 204 is disposed on the thin carrier film 216 with a sufficient thinness of less than or equal to 0.0005 inches, to be effective for enabling the EMI shielding material 200 to conform to an irregular surface on which the EMI shielding material 200 is intended to be or eventually applied. The metallized transfer layer or conductive metal layer 204 may be formed from various materials, which preferably are good electrical conductors, good thermal conductors and are relatively compliant, conformable, or flexible for conforming to a surface (e.g., a surface of a molded article, electrical component or heat sink, etc.). Using a material that is a good thermal conductor and capable of good conformance with a mating surface helps provide improved thermal conductivity. In addition, the material of the metallized transfer layer or conductive metal layer 204 may also help the EMI shielding material 200 to release cleanly and easily from an electrical component or heat sink, for example, for reworking or servicing the electrical component.

The metallized transfer layer or conductive metal layer 204 preferably comprises a copper or copper alloy, but may alternatively include one or more other materials including other metals besides copper (e.g., aluminum, silver, tin, etc.). By way of further example, exemplary embodiments may include a conductive metal layer 204 comprising aluminum having a thickness of less than or equal to about 0.0005 inches. Other embodiments may have a metallized transfer layer or conductive metal layer 204 with a thickness of about 0.0002 inches, 0.0001 inches, 5 angstroms, less than 0.0001 inches, less than 5 angstroms, 5 Nanometers (50 Angstroms), 100 Nanometers (1000 Angstroms), a value falling between 5 Nanometers and 100 Nanometers, etc. These numerical dimensions disclosed herein are provided for illustrative purposes only, as the dimensions may be varied for other embodiments depending, for example, on the particular application in which the embodiment will be used.

Also disclosed herein, the metallized transfer film or conductive metal layer 204 may be provided in some embodiments as a subcomponent or part of a product from the Dunmore Corporation of Bristol, Pa., such as products under the trade name Dun-Tran (e.g., Dunmore DT273 metallized film having a heat-activated adhesive layer, Dunmore DT101 metallization transfer layer, etc.) or other products having a metallization or metal layer or film with a polymer coating.

In this illustrated embodiment of FIG. 2, the metallized transfer layer or conductive metal layer 204 includes the release liner 230 and release coating 220 configured to allow for relatively clean and easy release of the EMI shielding material 200 from a surface of an electrical component or heat sink. Accordingly, the EMI shielding material 200 may be removed from the surface against which the release coating 220 and/or release liner 230 was positioned, where the release coating 220 and/or release liner 230 remains attached to or disposed along the metallized transfer layer or conductive metal layer 204. The presence of a release coating 220 and/or release liner 230 (e.g., polymer coating, dry film, transfer film, etc.) on at least a portion of the metallized transfer film or conductive metal layer 204 allows the EMI shielding material 200 to release cleanly and easily from mating components, for example, to permit ready access for reworking to a printed circuit board, central processing unit, graphics processing unit, memory module, or other heat-generating component. In addition, the metallized transfer layer or conductive metal layer 204 on the thin carrier film 216 and release coating 220 and/or release liner 230 may also provide one or more of the following advantages in some embodiments: reduced electrostatic discharge of the thermal interface material; preventing (or at least reduced possibility of) the conductive metal layer from contacting and possibly conducting current to mating surfaces; electrical isolation of the metallized transfer film or conductive metal layer; and/or light from light-emitting diodes (LEDs) or other light sources being reflected off the side of the film having the metallized transfer film or conductive metal layer.

The release liner 230 (and/or coating 220) may be disposed over the entire surface of the metallized transfer layer or conductive metal layer 204. Or, for example, the release liner 230 (and/or coating 220) may be disposed along two or more portions of the metallized transfer layer or conductive metal layer 204 on a side opposite the thin carrier film 216. By way of example, the release liner 230 (and/or coating 220) may be disposed on the metallized transfer layer or conductive metal layer 204 in a predetermined pattern (e.g., a striped pattern (FIG. 6), a dotted pattern (FIG. 7), combination thereof, among other patterns, etc.). In exemplary embodiments having the release liner 230 (and/or coating 220), the release liner or coating are preferably configured to allow for a relatively clean and easy release of the EMI shielding material 200 from the surface against which it is applied. The release coating or liner may thus allow for a clean release of the EMI shielding material 200 from a mating component, such as for obtaining access to the component for servicing, repair, replacement, etc.

The EMI shielding material 200 may be positioned, sandwiched, or installed between a heat sink and an electrical component (e.g., printed circuit board assembly, central processing unit, graphics processing unit, memory module, other heat-generating component, etc.). When in contact with a surface of the electrical component, a thermally conducting heat path may be established or defined from the electrical component, through the metallized transfer layer or conductive metal layer 204, the release liner 230 and/or coating 220 to the heat sink. In this example, the metallized transfer layer or conductive metal layer 204 may be applied to either the electrical component or heat sink, and the release liner 230 (and/or coating 220) may allow for a clean release of the EMI shielding material 200 from the electrical component or heat sink respectively, such as when the heat sink is removed for obtaining access to the electrical component for servicing, repair, replacement, etc.

The release liner 230 and release coating 220 may be configured to cause a preferential release from a preferred surface, in order to stay with or stick to a component to be shielded, or alternatively to stick to a heat sink. The release liner 230 and release coating 220 may allow for easier handling and installation by inhibiting adherence, stickiness or tacky surface tack, such as to the hands of the installer or to a surface of a component. In the illustrated embodiment of FIG. 2, the EMI shielding material 200 includes release liner 230 on a second side 212 of the metallized transfer layer or conductive metal layer 204. The EMI shielding material 200 additionally includes release coating 220 illustrated directly below the lower surface or second side 244 of the release liner 230.

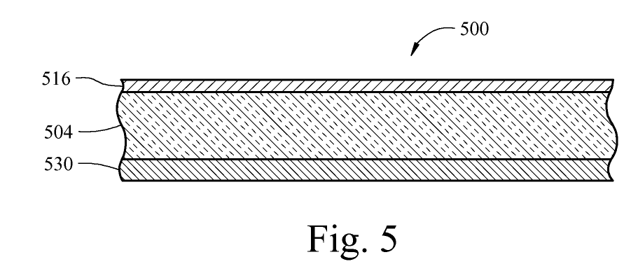

Various materials may be used for the release coating 220 and release liner 230 shown in FIG. 2 as well as the other exemplary embodiments disclosed herein. By way for example, the release liner 230 may comprise a substrate, supporting layer, film, or liner formed of paper, polyester propylene, etc., which has been siliconized to provide a release coating 220 thereon. Other embodiments may include a release liner 230 that is not treated (e.g., siliconized, etc.), but instead the dry material itself is configured to release from the carrier liner and transfer to the thermal interface material. For example, FIG. 5 illustrates an exemplary EMI shielding material 500 including a metallized transfer layer or conductive metal layer 504 disposed along the entire first side of a carrier film 516, and only a release liner 530 thereon. In this exemplary embodiment, the release liner 530 itself is preferably configured (in an untreated condition without a release coating) to release from a mating article or component to which the EMI shielding material is applied.

As just mentioned, the release liner 230 (FIG. 2) may be configured as a supporting substrate, layer, or film for the corresponding release coating 220, which, in turn, may be configured as a low surface energy coating on the supporting substrate, layer, or film, for example, to allow easy removal of the supporting substrate, layer, or film from the mating article or component. In some embodiments, a protective liner (see, for example, protective liner 140 in FIG. 1) may be provided so as to help protect the other layers 220, 230, 204, 216 of the EMI shielding material 200, for example, during transport, shipping, etc.

During an exemplary installation process, side 212 of the metallized transfer layer or conductive metal layer 204, or the exposed side of release coating 220 (where included), may be positioned generally against the surface of a molded article. The thin carrier film 216 may be colored or have a different color than the metallized transfer layer or conductive metal layer 204, such that the thin carrier film 216 is more readily recognizable and/or differentiated from the metallized or conductive metal layer 204. In turn, this coloring scheme (which may also be used in other disclosed embodiments herein, such as the illustrated embodiment of FIG. 1) may allow an installer to more quickly and easily determine the proper orientation for installing the metallized transfer layer or conductive metal layer 204, such as which side of the metallized transfer layer or conductive metal layer 204 should be placed in contact with the heat sink and which side should be placed in contact with the electronic component.

After the EMI shielding material 200 is applied, for example, to a surface of a electronic component, heat sink, or in a mold cavity, the carrier film 216 may be removed (e.g., peeled off, etc.) from the applied EMI shielding material 200. In some embodiments, the upper surface or side 224 of the metallized transfer layer or conductive metal layer 204 may further be positioned against and in thermal contact with a surface of a heat sink or electrical component (e.g., component of a high frequency microprocessor, printed circuit board, central processing unit, graphics processing unit, laptop computer, notebook computer, desktop personal computer, computer server, thermal test stand, etc.). The surface or side 224 of the metallized transfer layer or conductive metal layer 204 may be pressed against the component to establish good thermal contact with a surface of the component. In some embodiments, the upper surface or side 224 of the metallized transfer layer or conductive metal layer 204 may comprise a release liner 230 that is positioned against and in thermal contact with a surface of an electrical component, to permit the EMI shielding material 200 to be removed from the component for rework or replacement. The description provided above regarding an exemplary installation process for the EMI shielding material 200 is provided for purposes of illustration only, as other embodiments of an EMI shielding material may be configured and/or installed differently. For example, some embodiments include an EMI shielding material having a protective liner (see, for example, protective liner 140 in FIG. 1) on the surface of the release coating 220, which is removed prior to application of the EMI shielding material to a surface of an article, component, etc.

With continued reference to FIG. 2, the release coating 220 may have a respective layer thickness within a range of about 0.00025 inches and 00075 inches. The release liner 230 may have a respective layer thickness of about 0.001 inch. Some embodiments may include a release liner having thickness falling within a range of about 1 mil (0.025 millimeters) to about 10 mils (0.25 millimeters), such that the release liner may have a thickness of 1 mil, 10 mils, or any value falling between 1 mil and 10 mils. In one particular embodiment, the metallized transfer layer or conductive metal layer 204 may have a layer thickness of about 0.0005 inches. In another embodiment, the metallized transfer layer or conductive metal layer 204 may have a layer thickness of about 0.0002 inches. In a further embodiment, the metallized transfer layer or conductive metal layer 204 may have a layer thickness of about 0.0001 inches. In yet another embodiment, the metallized transfer layer or conductive metal layer 204 may have a layer thickness of about 5 angstroms. In additional embodiments, the metallized transfer layer or conductive metal layer 204 may have a layer thickness less than 0.0001 inches or less than 5 angstroms. In one or more exemplary embodiments, the conductive metal layer 104 may have a thickness falling within a range of about 5 Nanometers (50 Angstroms) to about 100 Nanometers (1000 Angstroms), such that the conductive metal layer 104 has a thickness of 5 Nanometers, 100 Nanometers, or any value falling between 5 Nanometers and 100 Nanometers. These numerical dimensions disclosed herein are provided for illustrative purposes only. The particular dimensions are not intended to limit the scope of the present disclosure, as the dimensions may be varied for other embodiments depending, for example, on the particular application in which the embodiment will be used.

It should be noted that other embodiments of EMI shielding materials may not include either one or both of release coating 220 and release liner 230. For example, another embodiment of an EMI shielding material generally includes a metallized transfer layer or conductive metal layer 204 on a thin carrier film 216, without any release coating 220 or release liner 230. Further embodiments of an EMI shielding material generally include a metallized transfer layer or conductive metal layer 204 on a thin carrier film 216, and a release coating (e.g., 220, etc.), without any release liner (e.g., 230, etc.) between the release coating 220 and the conductive metal layer 204. Additional embodiments of an EMI shielding material generally include a metallized transfer layer, or conductive metal layer 204 on a thin carrier film 216, and only a release liner (e.g., 230, etc.), such that the EMI shielding material does not include any release coating (e.g., 220, etc.).

FIG. 5 illustrates an exemplary embodiment of an EMI shielding material 500 in which a release liner 530 comprises a film or layer disposed continuously along an entire upper side of a metallized transfer layer or conductive metal layer 504. In other exemplary embodiments, an EMI shielding material may include a release liner disposed only along one or more portions of a side of a metallized transfer layer or conductive metal layer. In such embodiments, the release liner 530 may be disposed along the conductive metal layer in a pattern tailored for a custom release. In various embodiments, the release liner may be provided in predetermined pattern across a portion of the metallized transfer layer or conductive metal layer, such as a striped pattern (FIG. 6) or a uniform dotted pattern (FIG. 7). Accordingly, this allows for a customized level of tack or adherence to an article or component. As an example, the release liner patterned in a dot pattern may be used to hold a liner in place, but make an edge of the EMI shielding material relatively easy to lift off an article or component.

FIG. 6 illustrates an exemplary embodiment of an EMI shielding material 600 that allows for a customized level of tack or adherence to an article or component. The EMI shielding material 600 includes a release liner 630 disposed along one or more portions of a side of a metallized transfer layer or conductive metal layer 604. The release liner 630 is disposed along the conductive metal layer in a striped pattern tailored for a custom release.

FIG. 7 illustrates another exemplary embodiment of an EMI shielding material 700 that also includes a release liner 730 disposed along one or more portions of a side of a metallized transfer layer or conductive metal layer 704. The release liner 730 is disposed along the conductive metal layer 504 in a uniform dotted pattern.

Descriptions will now be provided of various exemplary methods for making or producing EMI shielding materials (e.g., 100 (FIG. 1), 200 (FIG. 2), 500 (FIG. 5), 600 (FIG. 6), 700 (FIG. 7), etc.). These examples are provided for purposes of illustration, as other methods, materials, and/or configurations may also be used.

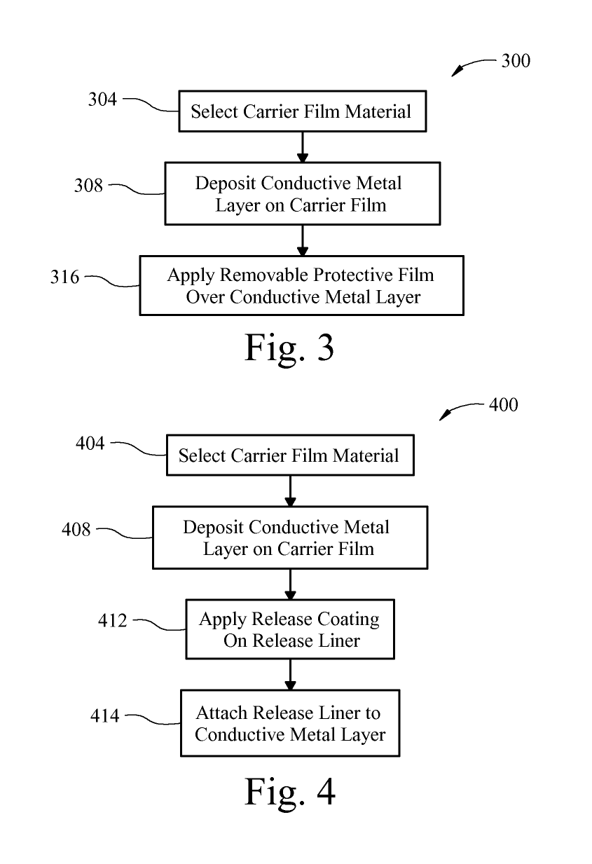

FIG. 3 illustrates an exemplary method 300 by which an EMI shielding material may be formed. In this particular exemplary method 300, process 304 includes a process, operation, or step indicated by box 304 of selecting a carrier film material (e.g., 116, etc.). A conductive metal layer (e.g., 104, etc.) may then be deposited on the carrier film at process, operation, or step indicated by box 308, such as by vapor deposition, vacuum metallization, sputtering, flash coating, electrolytic plating, evaporating, coating using gravure, flexographic coating, printing material in a pattern, other coating technologies, among other suitable processes. At box 316, a protective liner (e.g., 140, etc.) may be deposited over the conducive metal layer. The protective liner may be configured to protect the conductive metal layer of the EMI shielding material.

FIG. 4 illustrates another exemplary method 400 by which an EMI shielding material may be formed. In this particular exemplary method 400, a carrier film material (e.g., 216, etc.) may be selected at process, operation, or step indicated by box 404. A conductive metal layer (e.g., 204, etc.) may then be deposited on the carrier film at process, operation, or step indicated by box 408, such as by vapor deposition, vacuum metallization, sputtering, flash coating, electrolytic plating, evaporating, coating using gravure, flexographic coating, printing material in a pattern, other coating technologies, among other suitable processes. A release coating (e.g., 220, etc.) may be applied to a release liner (e.g., 230, etc.) at process, operation, or step indicated by box 412. The release liner (e.g., 230, etc.) may be applied to the conductive metal layer at process, operation, or step indicated by box 414. Alternative release liner materials may also be used, such as a release liner without a release coating thereon, where the release coating is instead placed directly in contact with the mating surface.

Process 400 may further include laminating the conductive metal layer (e.g., 204, a copper layer, an aluminum layer, a tin layer, one or more layers formed from other metals on a transfer film, etc.) to the release liner (e.g., 216, FIG. 2). By way of example, process 400 may include laminating a Dunmore DT273 metallized film having heat-activated adhesive layer to the exposed surface of a release liner 230. In which case, the release liner material and the Dunmore DT273 metallized film may thus be drawn between a pair of laminating rollers to form the completed EMI shielding material. As another example, process 400 may include laminating a Dunmore DT101 metallization transfer layer to the exposed surface of the release liner 230. In this latter example, the release liner material and the Dunmore DT101 metallization transfer layer may thus be drawn between a pair of laminating rollers to form the completed EMI shielding material. The Dunmore DT273 metallized film generally includes a siliconized (or release coating) liner (or supporting layer, substrate, or film) having a thickness of about 1 mil or 2 mil, which has been metallized with aluminum at about 0.1 mils thickness and to which a heat seal layer is deposited on top of the metallization layer with a thickness of about 0.3 mils. The Dunmore DT101 metallized transfer film is similarly constructed as the DT273 but without the heat seal layer.

Embodiments (e.g., 100, 200, 500, 600, 700, etc.) disclosed herein may be used with a wide range of electronic components, EMI sources, heat-generating components, heat sinks, among others. By way of example only, exemplary applications include printed circuit boards, high frequency microprocessors, central processing units, graphics processing units, laptop computers, notebook computers, desktop personal computers, computer servers, thermal test stands, portable communications terminals (e.g., cellular phones, etc.), etc. Accordingly, aspects of the present disclosure should not be limited to use with any one specific type of end use, molded article, electrical component, part, device, equipment, etc.

Numerical dimensions and the specific materials disclosed herein are provided for illustrative purposes only. The particular dimensions and specific materials disclosed herein are not intended to limit the scope of the present disclosure, as other embodiments may be sized differently, shaped differently, and/or be formed from different materials and/or processes depending, for example, on the particular application and intended end use.

It is envisioned that two or more specific exemplified values for a given parameter may define endpoints for a range of values that may be claimed for the parameter. For example, if a dimension or parameter X is exemplified herein to have value A and also exemplified to have value Z, it is envisioned that dimension or parameter X may have a range of values from about A to about Z. Similarly, it is envisioned that disclosure of two or more ranges of values for a dimension or parameter (whether such ranges are nested, overlapping or distinct) subsume all possible combination of ranges for the value that might be claimed using endpoints of the disclosed ranges. For example, if dimension or parameter X is exemplified herein to have values in the range of 1 to 10, or 2 to 9, or 3 to 8, it is also envisioned that dimension or parameter X may have other ranges of values including 1 to 9, 1 to 8, 1 to 3, 1 to 2, 2 to 10, 2 to 8, 2 to 3, 3 to 10, 3 to 9, etc.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments. Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

1. An EMI shielding material comprising:
a thin carrier film;
a conductive metal layer disposed on the thin carrier film,
wherein the thin carrier layer and conductive metal layer are configured to conform to an irregular surface of a mold cavity, such that the EMI shielding material may be insert molded onto a molded article; and
wherein the EMI shielding material imparts EMI shielding capability to a plastic article without requiring the plastic article to be made of a conductive plastic or painted with a conductive paint;
whereby the EMI shielding material is sufficiently compliant such that the conductive metal layer and thin carrier film are capable of conforming to an irregular surface when the EMI shielding material is applied to the irregular surface.

2. The EMI shielding material of claim 1, wherein the thin carrier film comprises at least one or more of polymer, teflon, polyester, acrylic, or plastic.

3. The EMI shielding material of claim 1, further comprising a protective liner disposed generally over the release coating on a side of the EMI shielding material opposite the thin carrier film.

4. The EMI shielding material of claim 1, wherein the conductive metal layer is disposed on the exterior of the plastic article and the thin carrier film is adhered to the plastic article.

5. The EMI shielding material of claim 1, wherein:
the thin carrier film has a thickness falling within a range of about 0.2 micrometers to about 5 micrometers; and
the conductive metal layer has a thickness falling within a range of about 5 Nanometers to about 100 nanometers.

6. An EMI shielding material comprising:
a thin carrier film;
a conductive metal layer disposed on the thin carrier film, the conductive metal layer having a thickness of less than or equal to 0.0005 inches; and
a release coating disposed on the EMI shielding material on a side opposite the thin carrier film, where the release coating is a low surface energy coating that allows for removal of the EMI shielding material from a surface in contact with the release coating;
whereby the conductive metal layer is sufficiently thin such that the EMI shielding material is capable of conforming to an irregular surface when the EMI shielding material is applied to the irregular surface.

7. The EMI shielding material of claim 6, further comprising at least one or more of a release coating, a release liner, and a protective liner disposed over the conductive metal layer.

8. The EMI shielding material of claim 6, further comprising a release liner disposed in a predetermined pattern along two or more portions of a side of the conductive metal layer opposite the thin carrier film.

9. The EMI shielding material of claim 6, further comprising a release liner disposed over the conductive metal layer and configured to allow for a relatively clean and easy release of the EMI shielding material from a surface in contact with the release liner.

10. The EMI shielding material of claim 9, wherein:
the thin carrier film has a thickness falling within a range of about 0.2 micrometers to about 5 micrometers;
the conductive metal layer has a thickness falling within a range of about 5 Nanometers to about 100 nanometers; and
the release liner has a thickness falling within a range of about 1 mil to about 10 mils.

11. The EMI shielding material of claim 6, wherein:
the thin carrier film has a thickness falling within a range of about 0.2 micrometers to about 5 micrometers; and
the conductive metal layer has a thickness falling within a range of about 5 Nanometers to about 100 nanometers.

12. The EMI shielding material of claim 6, wherein the thin carrier film comprises at least one or more of polymer, teflon, polyester, acrylic, or plastic.

13. The EMI shielding material of claim 6, further comprising a protective liner disposed generally over the release coating on a side of the EMI shielding material opposite the thin carrier film.

14. The EMI shielding material of claim 6, where the thin carrier film has a thickness of less than or equal to about 0.001 inches, whereby the thin carrier film is sufficiently thin such that the EMI shielding material is capable of conforming to an irregular surface when the EMI shielding material is applied to the irregular surface.

15. The EMI shielding material of claim 6, wherein:
the thin carrier film includes a first side;
the conductive metal layer is applied to the first side of the thin carrier film;
the conductive metal layer has a thickness of less than or equal to 0.0005 inches, and the thin carrier film has a thickness of less than or equal to about 0.001 inches;
whereby the conductive metal layer and the thin carrier film together have a combined thickness that is sufficiently thin to enable the EMI shielding material to conform to an irregular surface when the EMI shielding material is applied to the irregular surface.

16. A plastic article comprising the EMI shielding material of claim 15.

17. A plastic article comprising an EMI shielding material, the EMI comprising:
a thin carrier film; and
a conductive metal layer disposed on the thin carrier film, the conductive metal layer having a thickness of less than or equal to 0.0005 inches;
wherein the EMI shielding material imparts EMI shielding capability to the plastic article without requiring the plastic article to be made of a conductive plastic or painted with a conductive paint;
whereby the conductive metal layer is sufficiently thin such that the EMI shielding material is capable of conforming to an irregular surface when the EMI shielding material is applied to the irregular surface.

18. A method relating to the making of an EMI shielding material configured to conform to an irregular surface when the EMI shielding material is applied to irregular surface, the method comprising:
depositing conductive metal onto a carrier film having a thickness of less than or equal to about 0.001 inches, to thereby form a conductive metal layer having a thickness of less than or equal to 0.0005 inches; and
applying the EMI shielding material to a plastic article, whereby the EMI shielding material is operable for imparting EMI shielding capability to the plastic article.

19. The method of claim 18, wherein applying the EMI shielding material to a plastic article include applying the EMI shielding material to a surface within a mold cavity in which the plastic article is to be molded.

20. The method of claim 18, wherein the EMI shielding material imparts EMI shielding capability to the plastic article without having to make the plastic article out of a conductive plastic and without having to paint the plastic article with a conductive paint.

21. The method of claim 18, wherein:
the carrier film has a thickness falling within a range of about 0.2 micrometers to about 5 micrometers; and
the conductive metal layer has a thickness falling within a range of about 5 Nanometers to about 100 nanometers.

22. The method of claim 18, further comprising applying a release liner to the conductive metal layer.

23. The method of claim 22, wherein the release liner is applied such that the release liner has a thickness falling within a range of about 1 mil to about 10 mils.

24. The method of claim 22, further comprising applying a release coating to the release liner.

25. A method relating to the making of an EMI shielding material configured to conform to an irregular surface when the EMI shielding material is applied to irregular surface, the method comprising:
depositing conductive metal onto a carrier film having a thickness of less than or equal to about 0.001 inches, to thereby form a conductive metal layer having a thickness of less than or equal to 0.0005 inches; and
applying a release liner to the conductive metal layer, wherein applying the release liner includes:
laminating the conductive metal layer to an exposed surface of the release liner; and
drawing the conductive metal layer and the release liner between a pair of laminating rollers.

26. The method of claim 25, wherein the release liner is applied such that the release liner has a thickness falling within a range of about 1 mil to about 10 mils.

27. The method of claim 25, wherein:
the carrier film has a thickness falling within a range of about 0.2 micrometers to about 5 micrometers; and
the conductive metal layer has a thickness falling within a range of about 5 Nanometers to about 100 nanometers.

28. The method of claim 25, further comprising applying the EMI shielding material to a surface within a mold cavity.

29. The method of claim 25, further comprising applying a release coating to the release liner.
